(19) United States
(12) Patent Application Publication
(10) Pub. No.: US 2025/0160139 A1
(43) Pub. Date: May 15, 2025

(54) Display Device

(71) Applicant: LG Display Co., Ltd., Seoul (KR)

(72) Inventors: Seongjoo Lee, Paju-si (KR); JungSun Baek, Paju-si (KR)

(21) Appl. No.: 18/894,805

(22) Filed: Sep. 24, 2024

(30) Foreign Application Priority Data
Nov. 14, 2023 (KR) 10-2023-0157168

(51) Int. Cl. H10K 59/124; H10K 59/80

(52) U.S. Cl. CPC H10K 59/124; H10K 59/80518; H10K 59/878

(57) ABSTRACT

The present disclosure discloses a display device including a plurality of transistors over a substrate, a first insulating layer on at least one of the plurality of transistors and including a groove, a metal pattern layer in the groove, a second insulating layer on the first insulating layer and the metal pattern layer, and an electrode layer on the second insulating layer, located on the metal pattern layer, and overlapping with at least a portion of the metal pattern layer. The present disclosure providing advantages of improving luminous efficiency and improving reflective visibility characteristics.

### CROSS-REFERENCE TO RELATED APPLICATION

This application claims the priority benefit of Republic of Korea Patent Application No. 10-2023-0157168, filed on Nov. 14, 2023, which is hereby incorporated by reference in its entirety.

### TECHNICAL FIELD

The present disclosure relates to electronic devices with displays, and more specifically, to display devices.

### BACKGROUND

Along with the development of information and communication technology, display devices have become increasingly important for serving to provide various information on a display screen.

To provide various information to users, display devices may be required to have excellent display quality and high luminous efficiency.

In particular, the luminous efficiency is becoming increasingly important because display devices are required to use limited power as multimedia technology advances.

The luminous efficiency of display devices may be depended on the emission efficiency of light emitting elements included in the display devices.

Display devices including light emitting elements with high emission efficiency can have excellent luminous efficiency.

Therefore, to improve the luminous efficiency of display devices, it may be needed to improve the emission efficiency of light emitting elements.

However, there are several obstacles to improve the emission efficiency of light emitting elements.

### SUMMARY

To address these issues, although a display device having a structure in which a metal pattern layer is disposed under an electrode layer has been developed, this display device has a disadvantage of leading reflective visibility to be reduced due to a protruding portion of the electrode layer.

The display device has an additional disadvantage of showing asymmetric characteristics for each azimuth in viewing angle color shift due to the protruding portion of the electrode layer.

To address the foregoing issues, the inventors of the present disclosure have invented a display device in which an electrode layer is flattened without any protruding portion of an electrode layer.

One or more aspects of the present disclosure may provide a display device capable of improving light extraction efficiency and improving reflective visibility characteristics.

One or more aspects of the present disclosure may provide a display device capable of being driven with low power through high luminous characteristics by improving light extraction efficiency.

According to one or more example embodiments of the present disclosure, a display device comprises: a plurality of transistors over a substrate; a first insulating layer on at least one transistor among the plurality of transistors, the first insulating layer including a groove that extends through a portion of the first insulating layer in a direction towards the substrate; a metal pattern layer in the groove; a second insulating layer on the first insulating layer and the metal pattern layer, the second insulating layer covering the metal pattern layer; and an electrode layer on the second insulating layer and the metal pattern layer, the electrode layer overlapping at least a portion of the metal pattern layer.

In one embodiment, a display device comprises: a plurality of transistors over a substrate; a first insulating layer on at least one transistor among the plurality of transistors; a metal pattern layer on the first insulating layer; a second insulating layer on the first insulating layer and the metal pattern layer; an electrode layer on the second insulating layer and the metal pattern layer, the electrode layer overlapping with at least a portion of the metal pattern layer; and a bank layer on the second insulating layer and covering at least a portion of the electrode layer, the bank layer including an opening area, wherein a distance between a top surface of the metal pattern layer and a bottom surface of the electrode layer that overlaps the opening area is less than a distance between a top surface of the first insulating layer and the bottom surface of the electrode layer that overlaps the opening area.

In one embodiment, a display device comprises: a substrate; a transistor over the substrate; a first insulating layer over the transistor; a first metal pattern layer on the first insulating layer; a second insulating layer over the first metal pattern layer; an anode electrode on the second insulating layer, the anode electrode electrically connected to the transistor; a bank layer on the second insulating layer and a portion of the anode electrode, the bank layer having an opening; an emission layer on the anode electrode, the emission layer overlapping the opening of the bank layer; and a cathode electrode on the emission layer in the opening of the bank layer, wherein a width of the first metal pattern layer is less than a width of the opening and the first metal pattern layer overlaps the opening.

According to one or more aspects of the present disclosure, a display device may be provided that is capable of improving light extraction efficiency and improving reflective visibility characteristics.

According to one or more aspects of the present disclosure, a display device may be provided that is capable of being driven with low power through high luminous characteristics by improving light extraction efficiency.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure.

In the drawings:

FIG. 1 illustrates an example system configuration of a display device according to aspects of the present disclosure;

FIG. 2 is a plan view of the structure of an example portion of an active area of the display device according to a first example embodiment of the present disclosure;

FIG. 3 is an example cross-sectional view of an area taken along with line A-A′ of FIG. 2 and a portion of a non-active area;

FIG. 4 is a cross-sectional view of the structure of an example portion of the active area and an example portion of the non-active area of the display device according to a second example embodiment of the present disclosure;

FIG. 5 is a cross-sectional view of the structure of an example portion of the active area and an example portion of the non-active area of the display device according to a third example embodiment of the present disclosure;

FIG. 6 is a cross-sectional view of the structure of an example portion of the active area and an example portion of the non-active area of the display device according to a fourth example embodiment of the present disclosure;

FIGS. 7A to 7C illustrate an example process of forming the structure of the active area of the display device according to the first example embodiment of the present disclosure; and

FIGS. 8A to 8D illustrate an example process of forming the structure of the active area of the display device according to the third example embodiment of the present disclosure.

### DETAILED DESCRIPTION

Reference will now be made in detail to example embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, with reference to the accompanying drawings, various example embodiments of the present disclosure will be described in detail.

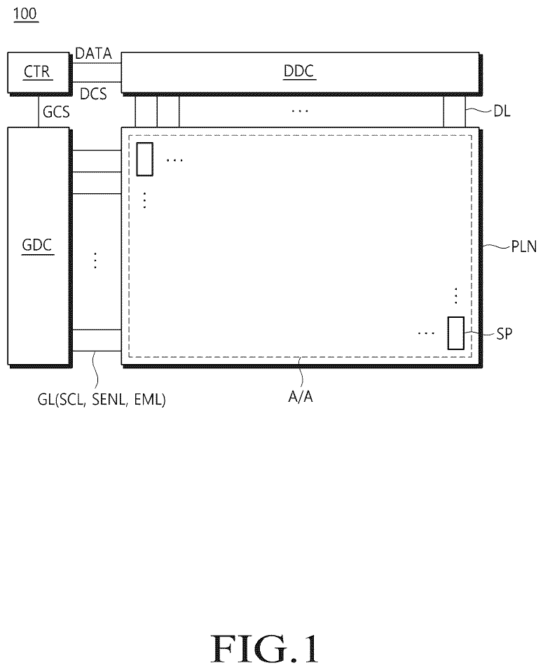

FIG. 1 illustrates an example system configuration of a display device according to aspects of the present disclosure.

Referring to FIG. 1, in one or more example embodiments, the display device 100 may include an organic light emitting display device, a lighting device, a light emitting device, and the like.

Hereinafter, for convenience of description, discussions on the touch display device 100 are provided based on an organic light emitting display device.

However, it should be understood that discussions provided below based on an organic light emitting display device may be equally or substantially equally to not only other types of display devices, but also a lighting device, a light emitting device, and the like including at least one transistor.

In one or more embodiments, the display device 100 may include a display panel PLN for displaying images or outputting light, and at least one driving circuit (or driver) for driving the display panel PLN.

In one or more embodiments, the display device 100 may have a bottom emission structure in which light emitted from light emitting elements is directed toward a substrate over which the light emitting elements are disposed, but example embodiments of the present disclosure are not limited thereto.

For example, the display device 100 may have a top emission structure in which light emitted from light emitting elements is directed toward a surface of the display device 100 opposite to a substrate over which the light emitting elements are disposed, or a dual emission structure in which light emitted from light emitting elements is directed toward both the substrate and the surface opposite to the substrate.

A plurality of data lines DL and a plurality of gate lines GL may be disposed in the display panel PLN.

In one or more embodiments, a plurality of subpixels SP defined by the plurality of data lines DL and the plurality of gate lines GL may be disposed in a matrix pattern in the display panel PLN.

The plurality of data lines DL and the plurality of gate lines GL may be configured to intersect each other in the display panel PLN.

For example, the plurality of gate lines GL may be arranged in one or more rows or columns, and the plurality of data lines DL may be arranged in one or more columns or rows.

Hereinafter, for convenience of description, discussions are provided based on examples where that the plurality of gate lines GL are arranged in one or more rows and the plurality of data lines DL are arranged in one or more columns.

In addition to the plurality of data lines DL and the plurality of gate lines GL, other types of signal lines may be disposed in the display panel PLN according to a subpixel structure and the like.

Types of signal lines disposed in the display panel PLN may change depending on a subpixel structure and the like.

Herein, each, or one or more, of signal lines may configured to include a respective electrode to which a signal is applied. For example, at least a part of a signal line may serve as an electrode to which a signal is applied.

The panel display PLN may include an active area A/A, which allows images to be displayed, and a non-active area N/A, which is an outer area or outer edge and does not allow images to be displayed.

The non-active area N/A may be referred to as a bezel area or a bezel.

A plurality of subpixels SP for displaying images may be disposed in the active area A/A.

A pad area to which a data driver DDC is electrically connected may be disposed in the non-active area N/A.

In one or more aspects, a plurality of data link lines for interconnecting the pad area and a plurality of data lines DL may be disposed in the non-active area N/A.

For example, the plurality of data link lines may be parts of the plurality of data lines DL extending to the non-active area N/A or be separate patterns electrically connected to the plurality of data lines DL.

In one or more aspects, gate driving related lines, which deliver a voltage (signal) needed for gate driving to a gate driver GDC through a pad to which the data driver DDC is electrically connected, may be disposed in the non-active area N/A.

For example, the gate driving related lines may include clock lines for delivering clock signals, gate voltage lines for delivering gate voltages (VGH, VGL), gate driving control signal lines for delivering various types of control signals required for generating scan signals, and the like.

The gate driving related lines may be disposed in the non-active area N/A, which are different from gate lines GL disposed in the active area A/A.

Driving circuits included in the display device 100 may include at least one data driver DDC for driving a plurality of data lines DL, at least one gate driver GDC for driving a plurality of gate lines GL, and a controller CTR for controlling the data driver DDR and the gate driver GDC.

The data driver DDC can drive the plurality of data lines DL by outputting data voltages to the plurality of data lines DL.

The gate driver GDC can drive the plurality of gate lines GL by outputting scan signals to the plurality of gate lines GL.

The controller CTR can control driving operations of the data driver DDC and the gate driver GDC by supplying various types of control signals (DCS, GCS) required for the driving operations of the data driver DDC and the gate driver GDC.

Further, the controller CTR can supply image data DATA to the data driver DDC.

The controller CTR can start to scan a pixel according to a timing scheduled in each frame.

The controller CTR can receive image data input from an internal or external device or system (e.g., a host system), supply image data DATA readable by the data driver DDC based on the input image data to the data driver DDC, and control, and causes a data voltage corresponding to the image data DATA to be written by the data driver DDC to a corresponding subpixel or pixel at a pre-configured time in accordance with scan operation by the gate driver GDC.

To control the data driver DDC and the gate driver GDC, the controller CTR can receive, from the internal or external device or system (e.g., the host system), timing signals, such as, a vertical synchronization signal Vsync, a horizontal synchronization signal Hsync, an input data enable (DE) signal, a clock signal, and the like, and generate various types of control signals using the received signals.

Thereafter, the controller CTR can supply the generated signals to the data driver DDC and the gate driver GDC.

In one or more aspects, to control the gate driver GDC, the controller CTR can output several types of gate control signals GCS including a gate start pulse GSP, a gate shift clock GSC, a gate output enable signal GOE, and the like.

In one or more embodiments, to control the data driver DDC, the controller CTR can output several types of data control signals DCS including a source start pulse SSP, a source sampling clock SSC, a source output enable signal SOE, and the like.

For example, the controller CTR may be implemented in a separate component from the data driver DDC.

In another example, the controller CTR and the data driver DDC may be integrally formed in a single integrated circuit.

The data driver DDC can drive a plurality of data lines DL by receiving image data DATA from the controller CTR and then supplying data voltages (or data signals) corresponding to the image data DATA to the plurality of data lines DL.

The data driver DDC may be referred to as a source driving circuit or a source driver.

The data driver DDC can transmit various signals to, or receive various signals from, the controller CTR through various interfaces.

The gate driver GDC can sequentially drive a plurality of gate lines GL by sequentially supplying scan signals to the plurality of gate lines GL.

The gate driver GDC may be referred to as a scan driving circuit or a scan driver.

The gate driver GDC can sequentially supply scan signals with an on-voltage level or an off-voltage level to the plurality of gate lines GL by the control of the controller CTR.

When specific gate lines are selected and driven by the gate driver GDC, the data driver DDC can convert image data DATA received from the controller CTR into analog data voltages and supply the obtained data voltages to a plurality of data lines DL.

In one or more aspects, the data driver DDC may be located in, and/or electrically connected to, but not limited to, one side or portion (e.g., an upper edge or a lower edge) of the display panel PLN.

In one or more embodiments, the data driver DDC may be located in, and/or electrically connected to, but not limited to, two sides or portions (e.g., an upper edge and a lower edge) of the display panel PLN or at least two of four sides or portions (e.g., the upper edge, the lower edge, a left edge, and a right edge) of the display panel PLN according to driving schemes, panel design schemes, or other design requirements.

In one or more embodiments, the data driver GDC may be located in, and/or electrically connected to, but not limited to, one side or portion (e.g., an upper edge or a lower edge) of the display panel PLN.

In one or more embodiments, the data driver GDC may be located in, and/or electrically connected to, but not limited to, two sides or portion (e.g., a left edge and a right edge) of the display panel PLN or at least two of four sides or portions (e.g., the right edge, the right edge, an upper edge, and a lower edge) of the display panel PLN according to driving schemes, panel design schemes, or other design requirements.

The data driver DDC may be implemented by including one or more source driver integrated circuits SDIC.

Each source driver integrated circuit SDIC may include a shift register, a latch circuit, a digital-to-analog converter DAC, an output buffer, and the like.

In one or more aspects, the data driver DDC may further include one or more analog-to-digital converters ADC.

Each source driver integrated circuit SDIC may be connected to a conductive pad such as a bonding pad of the display panel PLN by a tape-automated-bonding (TAB) technique or a chip-on-glass (COG) technique.

In one or more embodiments, each source driver integrated circuit SDIC may be directly disposed in the display panel PLN.

In one or more embodiments, each source driver integrated circuit SDIC may be integrated into the display panel PLN

In one or more embodiments, each source driver integrated circuit SDIC may be connected to the display panel 110 by a chip-on-film (COF) technique.

In this implementation, each source driver integrated circuit SDIC may be mounted on a circuit film.

Each source driver integrated circuit SDIC mounted on the circuit film may be electrically connected to at least one data lines DL in the display panel PLN through the circuit film.

The gate driver GDC may include a plurality of gate driving circuits GDC.

The plurality of gate driving circuits GDC may correspond to a plurality of gate lines GL, respectively.

Each gate driving circuit GDC may include a shift register, a level shifter, and the like.

Each gate driving circuit GDC may be connected to a conductive pad such as a bonding pad of the display panel PLN by the tape-automated-bonding (TAB) technique or the chip-on-glass (COG) technique.

In one or more aspects, each gate driving circuit GDC may be connected to the display panel PLN by the chip-on-film (COF) technique.

In this implementation, each gate driving circuit GDC may be mounted on a circuit film.

Each gate driving circuit GDC mounted on the circuit film may be electrically connected to at least one gate line GL in the display panel PLN through the circuit film.

In this implementation, each gate driving circuit GDC may be embedded into the display panel PLN by a gate-in-panel (GIP) technique.

Accordingly, each gate driving circuit GDC may be directly formed in the display panel PLN.

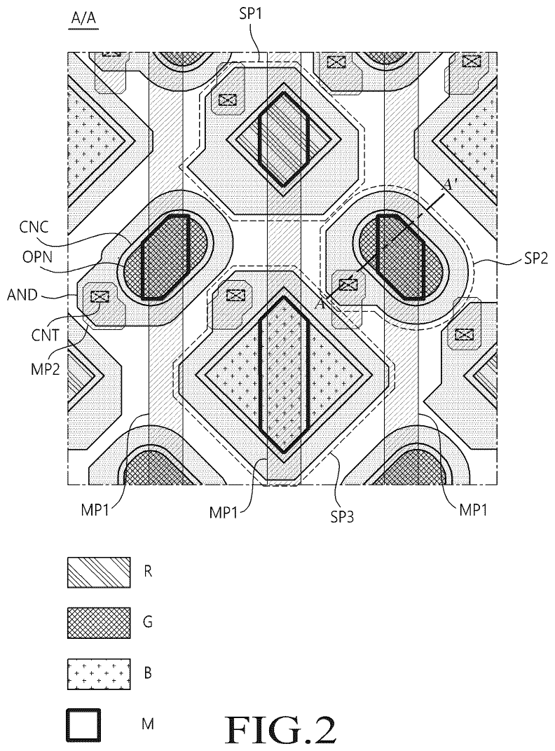

FIG. 2 is a plan view of the structure of an example portion of an active area AA of the display device 100 according to a first example embodiment of the present disclosure.

Referring to FIG. 2, in a first example embodiment, the display device 100 may include subpixels (SP1, SP2, and SP3).

The subpixels (SP1, SP2, and SP3) may be referred to as a first subpixel SP1, a second subpixel SP2, and a third subpixel SP3, respectively.

Discussions on the configuration of FIG. 2 are provided based on an example where the first subpixel SP1 is a red subpixel R, the second subpixel SP2 is a green subpixel G, and the third subpixel SP3 is a blue subpixel B.

It should be noted here that although each pixel may further include a white subpixel, for convenience of description, discussions on the configuration of FIG. 2 are provided based on the example where each pixel includes a red subpixel R, a green subpixel G, and a blue subpixel B.

It should be also understood that the configuration of subpixels (SP1, SP2, and SP3) in the plan view of FIG. 2 is one example among applicable examples. Thus, example embodiments of the present disclosure are not limited thereto, and various configurations or various combinations of subpixels may be applied.

In one or more embodiments, each of subpixels may include a pixel circuit including at least one metal pattern layer (MP1 and/or MP2) and a light emitting element including an anode layer AND. For example, the light emitting element may include an organic light emitting diode (OLED), a micro light emitting diode (LED), a mini light emitting diode (LED), a quantum dot light emitting diode (QLED), and the like.

Each of the subpixels (SP1, SP2, and SP3) may include an opening area OPN, and a recessed portion CNC defined by the opening area OPN.

For example, the opening area OPN may refer to an opening of a bank layer (not shown), and the opening area OPN may be surrounded by an inclined portion or inclined surface of the recessed portion CNC.

A respective light emitting area of each of the subpixels (SP1, SP2, and SP3) may be defined by a corresponding opening area OPN.

For example, a respective light emitting area of each of the subpixels (SP1, SP2, and SP3) may be substantially the same as or nearly the same a corresponding opening area OPN.

Herein, substantially the same or nearly the same may mean a degree of being considered as being equivalent to each other taking into account minute differences due to errors in the process of manufacturing the display panel 110 or display device 100.

In one or more embodiments, subpixels emitting light of different colors may include opening areas (OPN) having areas or sizes different from each other.

For example, the area or size of an opening area through which blue light is emitted may be the largest, and the area or size of an opening area through which red light is emitted may be the smallest.

This is because element characteristics of light emitting elements included in subpixels emitting light of different colors may be different.

However, example embodiments of the present disclosure are not necessarily limited to this, and opening areas may have the same size or area regardless of colors of light emitted from subpixels.

In one or more embodiments, the recessed portion CNC formed in each of the subpixels (SP1, SP2, and SP3) may include a flat portion and an inclined portion surrounding the flat portion.

In one or more embodiments, an anode layer AND, which is configured to cover the flat portion and the inclined portion of the recessed portion CNC, may be disposed on the recessed portion CNC.

In one or more embodiments, the display device may include at least one metal pattern layer (MP1 and/or MP2) electrically connected to the anode layer AND.

The at least one metal pattern layer may include a first metal pattern layer MP1 overlapping with a half tone mask (HTM) area M and a second metal pattern layer MP2 electrically connected to the anode layer AND through a contact portion CNT.

For example, the anode layer AND and the second metal pattern layer MP2 may be electrically connected through the contact portion CNT.

Referring to FIG. 2, when an insulating layer (not shown) is formed on a substrate (not shown), a groove M may be formed, by applying a half tone mask (HTM), in a portion where the first metal pattern layer (MP1, 610) is formed so that the anode layer AND cannot protrude in the opening area OPN.

The groove M may be substantially the same as the half tone mask (HTM) area.

In a plane view, the groove M may be formed in the opening area OPN, and be configured not to extend beyond the recessed portion CNC.

The groove M may be disposed across the opening area OPN.

A width of the groove M may be smaller than (e.g., less than) that of the opening area OPN and larger than that of the first metal pattern layer (MP1, 610). In one embodiment, the width of the first metal pattern layer 610 is less than a width of the opening area OPN and overlaps the opening area OPN. At least one of the subpixels (SP1, SP2, and SP3) has a first light emitting area in a corresponding opening area OPN, and a second light emitting area in a corresponding recessed portion CNC at which light emitted from a corresponding first light emitting area is reflected and caused to move out of the recessed part CNC.

The second light emitting area may surround the first light emitting area and the opening area OPN along the shape of the recessed portion CNC.

For example, a corresponding groove M may be configured to overlap with the first light emitting area and not overlap with the second light emitting area.

In one or more embodiments, an anode layer AND in a half tone mask (HTM) area M in an opening area OPN may be flattened.

As the anode layer AND is flattened, rainbow mura that occurs when reflective visibility caused by a step of the anode layer AND is reduced can be suppressed, and asymmetric characteristics for each azimuth in a viewing angle color shift due to the step of the anode layer AND can be suppressed.

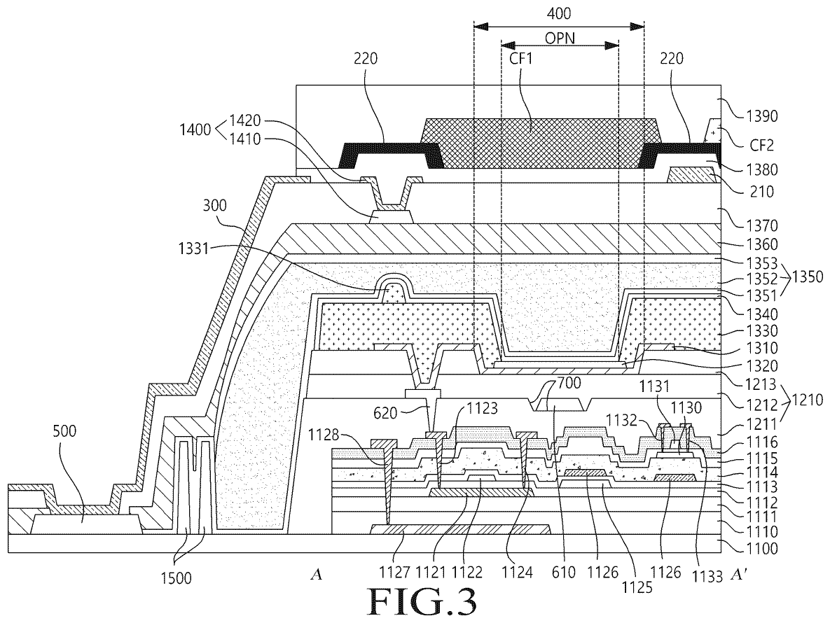

FIG. 3 is an example cross-sectional view of an area taken along with line A-A′ of FIG. 2 and a portion of a non-active area according to one embodiment.

In one or more embodiments, FIG. 3 may represent an area of the display device corresponding to an area where a plurality of subpixels SP are disposed and a portion of the non-active area.

Referring to FIG. 3, in one or more embodiments, the display device may include a substrate 1100, an insulating layer 1210 located on the substrate, a first electrode layer 1310 (e.g., an anode electrode) located on the insulating layer 1210, a bank layer 1330 located on respective portions of the first electrode layer 1310 and the insulating layer 1210, an emission layer 1320 located on the first electrode layer 1310, a second electrode layer 1340 located on the emission layer 1320 and the bank layer 1330, an encapsulation layer 1350 located on the second electrode layer 1340, a touch buffer layer 1360 located on the encapsulation layer 1350, a touch interlayer insulating layer 1370 located on the touch buffer layer 1360, and a passivation layer 1380 located on touch interlayer insulating layer 1370.

The display device 100 may include a first transistor located on the substrate 1100 in the active area A/A and an organic light emitting element, for example, an organic light emitting diode, which is electrically connected to the first transistor.

The first transistor may include a first active layer 1121, a first gate electrode layer 1122, a first source electrode layer 1123, and a first drain electrode layer 1124.

The organic light emitting element may include the first electrode layer 1310, the emission layer 1320, and the second electrode layer 1340.

For example, the first electrode layer 1310 may be an anode electrode layer, and the second electrode layer 1340 may be a cathode electrode layer, but example embodiments of the present disclosure are not limited thereto.

It should be noted that the first electrode layer 1310 may be substantially the same as the anode electrode layer AND in the configuration of FIG. 2.

Referring to FIG. 3, alight shielding layer 1127 may be disposed on the substrate 1100.

A first buffer layer 1110 may be disposed on the substrate 1100 and the light shielding layer 1127, and a second buffer layer 1111 may be disposed on the first buffer layer 1110.

The first active layer 1121 of the first transistor may be disposed on the second buffer layer 1111.

The first active layer 1121 of the first transistor may be disposed on the second buffer layer 1111.

A first gate insulating layer 1112 may be disposed on the first active layer 1121, and the first gate electrode layer 1122 may be disposed on the first gate insulating layer 1112.

A first interlayer insulating layer 1113 may be disposed on the first gate electrode layer 1122, a third buffer layer 1114 may be disposed on the first interlayer insulating layer 1113, a second gate insulating layers 1115 may be disposed on the third buffer layer 1114, and a second interlayer insulating layer 1116 may be disposed on the second gate insulating layer 1115.

A light shielding electrode layer 1128, the first source electrode layer 1123, and the first drain electrode layer 1124 may be disposed on the second interlayer insulating layer 1116.

The first source electrode layer 1123 and the first drain electrode layer 1124 may be configured to be spaced apart from each other on the second interlayer insulating layer 1116.

The first source electrode layer 1123 and the first drain electrode layer 1124 may be configured to contact respective portions of the first active layer 1121 through holes in the first gate insulating layer 1112, the first interlayer insulating layer 1113, the third buffer layer 1114, the second gate insulating layer 1115, and the second interlayer insulating layer 1116.

As described above, the first transistor may be disposed over the substrate 1100, but the structure of the first transistor according to example embodiments of the present disclosure is not limited to this.

In another example, the first gate electrode layer 1122 may be disposed on the substrate 1100, the first active layer 1121 may be disposed on the first gate electrode layer 1122, the first source electrode layer 1123 may be disposed on the first active layer 1121 and configured to overlap with a first portion of the first active layer 1121, and the first drain electrode layer 1124 may be configured to overlap with a second opposing portion of the first active layer 1121.

The insulating layer 1210 may be configured to cover the first transistor.

The insulating layer 1210 may include an organic material, but example embodiments of the present disclosure are not limited thereto.

The insulating layer 1210 may include a first insulating layer 1211, a second insulating layer 1212, and a third insulating layer 1213.

For example, the first insulating layer 1211 may be configured to cover the first transistor, the second insulating layer 1212 may be disposed on the first insulating layer 1121, and the third insulating layer 1213 may be disposed on the second insulating layer 1212.

However, example embodiments of the present disclosure are not limited thereto. The first insulating layer 1211 may be formed in a single layer, or include four or more insulating layers.

The insulating layer 1210 may include a recessed portion 400 having a flat portion and an inclined portion surrounding the flat portion.

FIG. 3 illustrates an example where the insulating layer 1210 is disposed in a green subpixel G, and the recessed portion 400 is located in the green subpixel G.

For example, the second insulating layer 1212 may include the flat portion, and the third insulating layer 1213 may include the inclined portion SLO.

However, example embodiments of the present disclosure are not limited thereto. For example, one insulating layer (e.g., the second insulating layer 1212 or the third insulating layer 1213) may include both the flat portion and the inclined portion of the recessed portion 400.

The flat portion of the recessed portion 400 may be a portion whose surface is parallel to the surface of the substrate 1100. The inclined portion of the recessed portion 400 may be a portion surrounding the flat portion, and the surface of the inclined portion may have a predetermined angle to the surface of the substrate 1100. The inclined portion exposed an inclined surface of the third insulating layer 1213 and the flat portion exposes a flat portion of the second insulation layer 1212. In one embodiment, the first electrode layer 1310 contacts the inclined surface of the third insulating layer 1213 and the flat portion of the second insulation layer 1212 that are respectively exposed by the inclined surface and the flat portion of the recessed portion 400.

In other words, the surface of the inclined portion may not be parallel to the surface of the substrate 1100.

In one or more embodiments, the insulating layer 1210 may have a contact hole spaced apart from the recessed portion 400.

In one or more embodiments, the first electrode layer 1310 may be disposed on one or more portions of the insulating layer 1210 and the recessed portion 400 in at least one subpixel area.

As described above, in at least one subpixel, the insulating layer 1210 may include at least one contact hole spaced apart from the recessed portion 400, and the first transistor and the first electrode layer 1310 of the organic light emitting element such as an organic light emitting diode and the like may be electrically connected to each other through the contact hole of the insulating layer 1210.

The bank layer 1330 may be disposed on the insulating layer 1210, cover at least a portion of the first electrode layer 1310, and include an opening area OPN. For example, the opening area OPN may be surrounded by the inclined portion of the recessed portion 400.

The bank layer 1330 may have the opening area OPN configured to expose a portion of the top surface of the first electrode layer 1310 in an area overlapping with the recessed portion 400.

The opening area OPN may correspond to a partial area of the flat portion of the recessed portion 400.

The corresponding of the opening area OPN to the partial area of the flat portion of the recessed portion 400 may mean that the opening area OPN overlaps with a portion of the flat portion in the subpixel.

Accordingly, at least one subpixel may have an area where the first electrode layer 1310 does not overlap with the bank layer 1330.

In one or more embodiments, the emission layer 1320 of the organic light emitting element may be disposed on a portion of the first electrode layer 1310 that is non-overlapping with the bank layer 1330.

The emission layer 1320 may be disposed on the first electrode layer 1310 and the bank layer 1330.

The second electrode layer 1340 of the organic light emitting element may be disposed on the emission layer 1320.

In one or more embodiments, the emission layer 1320 of the organic light emitting element may be formed by a method of deposition or coating having straightness.

For example, the emission layer 1320 may be formed by a physical vapor deposition (PVD) method.

The emission layer 1320 formed by these methods may be configured such that a thickness of an area with a predefined angle to the substrate 1100 is smaller than a thickness of an area parallel to the substrate 1100.

Therefore, when the organic light emitting element is driven, current density may be highest in an area where the thickness of the emission layer 1320 1320 is relatively thin, that is, an area corresponding to the inclined portion of the recessed portion 400. Therefore, strong electric field may be generated in the area corresponding to the inclined portion of the recessed portion 400.

Thereby, a light emitting characteristic of the organic light emitting element in the area corresponding to the inclined portion of the recessed portion 400 and a light emitting characteristic of the organic light emitting element in an area corresponding to the flat portion of the recessed portion 400 may become different from each other, and in turn, the degradation of the organic light emitting element may become advanced.

In one or more embodiments, the emission layer 1320 may include a red organic emission layer included in a red subpixel R, a green organic emission layer included in a green subpixel G, and a blue organic emission layer included in a blue subpixel B.

FIG. 3 illustrates an example where the emission layer 1320 is, for example, a green organic emission layer.

In one or more embodiments, the bank layer 1330 may be configured to cover the inclined portion of the recessed portion 400. Thereby, the advanced degradation of the organic light emitting element in the area corresponding to the inclined portion of the recessed portion 400 can be prevented or at least reduced, and the problem of representing different light emitting characteristics for each area can be prevented.

However, thickness conditions of the emission layer 1320 according to example embodiments of the present disclosure are not limited to this, and the emission layer 1320 may have a respective thickness in each portion of the emission layer 1320.

In one or more embodiments, the first electrode layer 1310 may include a reflective metal.

FIG. 3 illustrates that the first electrode layer 1310 is formed in a single layer, but example embodiments of the present disclosure are not limited thereto. For example, the first electrode layer 1310 may have a stack of multiple layers.

For example, when the first electrode layer 1310 includes multiple layers, at least one layer may include a reflective metal.

For example, the first electrode 1310 may include at least one of aluminum (Al), neodium (Nd), nickel (Ni), titanium (Ti), tantalum (Ta), copper (Cu), silver (Ag), and aluminum alloy, but example embodiments of the present invention are not limited thereto.

The second electrode layer 1340 may include a conductive material capable of transmitting or semi-transmitting light.

For example, the second electrode layer 1340 may include at least one of transparent conductive oxides, such as indium tin oxide (ITO), indium zinc oxide (IZO), indium tin zinc oxide (ITZO), zinc oxide, tin oxide, and the like, or include a semi-transmissive metal, such as magnesium (Mg), silver (Ag), an alloy of Mg and Ag, and the like.

In an example where the second electrode layer 1340 includes a semi-transmissive metal, the thickness of the second electrode layer 1340 may be smaller than the thickness of the first electrode layer 1310.

In one or more embodiments, the light shielding layer 1127, the light shielding electrode layer 1128 electrically connected to the light shielding layer 1127, and a second metal pattern 620 located on the first insulating layer 1211 may be disposed over the substrate 1100.

The light shielding layer 1127 may function as a capacitor or shield light coming from the back of the display panel 110 or display device 100.

The light shielding electrode layer 1128 may contact the light shielding layer 1127 through holes in the first buffer layer 1110, the second buffer layer 1111, the first gate insulating layer 1112, the first interlayer insulating layer 1113, the third buffer layer 1114, the second gate insulating layer 1115, and the second interlayer insulating layer 1116.

The second metal pattern layer 620 may contact the first source electrode layer 1123 through a hole in the first insulating layer 1211, and contact the first electrode layer 1310 through holes in the second insulating layer 1212 and the third insulating layer 1213.

For example, the second metal pattern layer 620 may serve to electrically interconnect the first source electrode layer 1123 and the first electrode layer 1310.

In one or more embodiments, as shown in FIG. 3, a storage capacitor may be disposed in the active area A/A.

The storage capacitor may include a first storage capacitor electrode layer 1125 disposed in the same layer as the first gate electrode layer 1122 and a second storage capacitor electrode layer 1126 disposed on the first interlayer insulating layer 1113. However, the structure of the storage capacitor according to example embodiments of the present disclosure is not limited to this.

As shown in FIG. 3, the second storage capacitor electrode layer 1126 may form a capacitor with a second gate electrode layer 1131 of a second transistor different from the first transistor.

A second active layer 1130 of the second transistor may be disposed on the third buffer layer 1114.

The second gate insulating layer 1115 may be disposed on the second active layer 1130, and the second gate electrode layer 1131 may be disposed on the second gate insulating layer 1115.

The second interlayer insulating layer 1116 may be disposed on the second gate electrode layer 1131, and the insulating layer 1210 may be disposed on the second interlayer insulating layer 1116.

A second source electrode layer 1132 and a second drain electrode layer 1133 may be disposed on the second interlayer insulating layer 1116.

The second source electrode layer 1132 and the second drain electrode layer 1133 may be configured to be spaced apart from each other on the second interlayer insulating layer 1116.

The second source electrode layer 1132 and the second drain electrode layer 1133 may contact respective portions of the second active layer 1130 through holes in the second interlayer insulating layer 1116.

In one or more embodiments, at least one spacer 1331 may be disposed between the second electrode layer 1340 and the bank layer 1330. The spacer 1331 is between the bank layer 1330 and the second electrode layer 1340.

The at least one spacer 1331 may be configured to overlap with the contact portion CNT of FIG. 2.

As the holes (which may referred to as a contact portion CNT) in the second insulating layer 1212 and the third insulating layer 1213, which allow the second metal pattern layer 620 to contact the first electrode layer 1310, is filled with a portion of the bank layer 1330, and the spacer 1331 is disposed over the contact portion CNT, a height of the bank layer 1330 including the portion in the contact portion CNT may be greater than a height of the bank layer 1330 partially overlapping with the recessed portion 400.

The spacer 1331 may include the same material as the bank layer 1330, but example embodiments of the present disclosure are not limited thereto.

The bank layer 1330 and the spacer 1331 may include a transparent insulating material.

The transmittance of the bank layer 1330 may be higher than the transmittance of the third insulating layer 1213.

In one or more embodiments, at least one encapsulation layer 1350 may be disposed on the second electrode layer 1340 of the organic light emitting element.

The encapsulation layer 1350 may include a first encapsulation layer 1351 disposed on the second electrode layer 1340, a second encapsulation layer 1352 disposed on the first encapsulation layer 1351, and a third encapsulation layer 1353 disposed on the second encapsulation layer 1352.

As such, when the encapsulation layer 1350 includes multiple layers, at least one layer may include an inorganic insulating material, and at least another layer may include an organic insulating material.

For example, each of the first encapsulation layer 1351 and the third encapsulation layer 1353 may include an inorganic insulating material, and the second encapsulation layer 1352 may include an organic insulating material, but example embodiments of the present disclosure are not limited thereto.

The encapsulation layer 1350 disposed on the organic light emitting element can prevent moisture or undesirable substances or particles from penetrating into the organic light emitting element.

The touch buffer layer 1360 may be disposed on the third encapsulation layer 1353, and the touch interlayer insulating layer 1370 may be disposed on the touch buffer layer 1360.

A plurality of touch sensors 210 may be disposed on the touch interlayer insulating layer 1370.

Touch sensors 210 may be transparent or opaque.

The passivation layer 1380 may be disposed on the plurality of touch sensors 210.

A plurality of black matrices 220 may be disposed on the passivation layer 1380.

The black matrices 220 may include a material with low reflectance.

For example, the black matrices 220 may include carbon black, dye, or resin.

Color filters (CF1 and CF2) may be located on the passivation layer 1380 and located in an area corresponding to the recessed portion 400.

FIG. 3 illustrates that a green color filter CF1 and a blue color filter CF2 are disposed between a plurality of black matrices 220.

As the display panel 110 or display device 100 includes the color filters (CF1 and CF2), the display panel 110 can achieve high luminance efficiency.

In one or more embodiments, an overcoat layer 1390 may be disposed on the passivation layer 1380 and configured to cover the plurality of black matrices 220 and the color filters (CF1 and CF2).

The overcoat layer 1390 can prevent or at least reduce moisture or undesirable substances or particles from penetrating and prevent or at least reduce materials such as metal from corroding by reacting with moisture in the air.

In one or more embodiments, one or more connection patterns 1400 may be located on the touch buffer layer 1360 and under the black matrices 220.

The connection pattern 1400 may include a first connection pattern 1410 located on the touch buffer layer 1360, and a second connection pattern 1420 electrically connected to at least one of a plurality of touch sensors 210.

The first connection pattern 1410 and the second connection pattern 1420 may contact each other through a hole in the touch interlayer insulating layer 1370.

At least one dam 1500 may be disposed outside of the encapsulation layer 1350.

FIG. 3 illustrates that only one dam 1500 is disposed on the substrate 1100, but example embodiments of the present disclosure are not limited to this. The number of dams 1500 may be appropriately changed depending on the size of the display device 100 or design requirements.

FIG. 3 illustrates that the dam 1500 has two partition walls, but example embodiments of the present disclosure are not limited thereto. For example, the number of partition walls of the dam 1500 may be three or more depending on design requirements.

In one or more embodiments, one or more touch lines 300 may be disposed on the touch interlayer insulating layer 1370.

Two or more touch sensors 210 may be electrically connected to each other through one or more connection patterns 1400 and thereby, form one driving touch electrode line or one sensing touch electrode line.

FIG. 3 illustrates that the touch sensors 210 and the touch line 300 are located on the same layer, but example embodiments of the present disclosure are not limited to this. For example, and the touch sensors 210 and the touch line 300 may be located in different layers.

The touch line 300 may be located over the dam 1500 and extend to a pad portion 500 located outside of the dam 1500.

The touch line 300 may be electrically connected to the pad portion 500.

For example, the touch line 300 may be electrically connected to the pad portion 500 disposed in the non-active area of the display panel 110.

The pad portion 500 to which the touch line 300 is connected may be connected to a touch sensing circuit (not shown).

The touch sensing circuit (not shown) can supply a touch driving signal to at least one of a plurality touch sensors 210, and can detect whether a touch is applied and/or a location of the touch (or touch coordinates) in response to the touch driving signal.

The touch line 300, the touch interlayer insulating layer 1370, the touch buffer layer 1360, and the encapsulation layer 1350 may be located on the dam 1500 and configured to overlap with the dam 1500, but example embodiments of the present disclosure are not limited to this.

Referring to FIG. 3, the first insulating layer 1211 may be disposed on at least one of the first transistor and the second transistor, and include a groove 700. In one embodiment, the groove 700 extends through a part of a thickness of the first insulating layer 1211 in a direction towards the substrate 1100.

In one or more embodiments, a first metal pattern layer 610 may be disposed in the groove 700, and the second insulating layer 1212 may be disposed on the first insulating layer 1211 and the first metal pattern layer 610 so as to cover the first metal pattern layer 610. In one embodiment, the first metal pattern layer 610 is confined within the groove 700 so as not to extend outside of the groove 700.

The first metal pattern layer 610 disposed in the groove 700 may be electrically connected to the first electrode layer 1310.

For example, the first electrode layer 1310 may be electrically connected to the second metal pattern layer 620, and the second metal pattern layer 620 may be electrically connected to the first metal pattern layer 610.

In one or more embodiments, the metal pattern layers (610 and 620) may be formed from a mesh structure, but example embodiments of the present disclosure are not necessarily limited thereto.

The first metal pattern layer 610 may be substantially the same as the first metal pattern layer MP1 in the configuration of FIG. 2.

The first electrode layer 1310 may be disposed on the second insulating layer 1212, be located on the first metal pattern layer 610, and overlap with at least a portion of the first metal pattern layer 610.

A half tone mask (HTM) may be applied to form the groove 700, in which the first metal pattern layer 610 is disposed.

In this implementation, a width of the first metal pattern layer 610 may be equal to or smaller than a width of a half tone mask (HTM) area.

The thickness of the metal pattern layer 610 may designed to be substantially the same as the depth of the groove 700, and thereby, the first electrode layer 1310 can be flattened without a step.

When the first insulating layer 1211 does not include the groove 700, the first electrode layer 1310 may have a step along the shape of the first metal pattern layer 610 due to the first metal pattern layer 610. Thereby, rainbow mura may be caused, this leading reflective visibility to be reduced.

In addition, the configuration in which the first insulating layer 1211 does not include the groove 700 may cause asymmetric characteristics for each azimuth in a viewing angle color shift due to the step of the first electrode layer 1310.

As described above, as the depth of the groove 700 and the thickness of the metal pattern layer 610 are designed to be substantially the same, the display device 100 can provide advantages of suppressing rainbow mura caused when reflective visibility is reduced due to the step of the first electrode layer 1310, and suppressing asymmetric characteristics for each azimuth in a viewing angle color shift caused due to the step of the first electrode layer 1310.

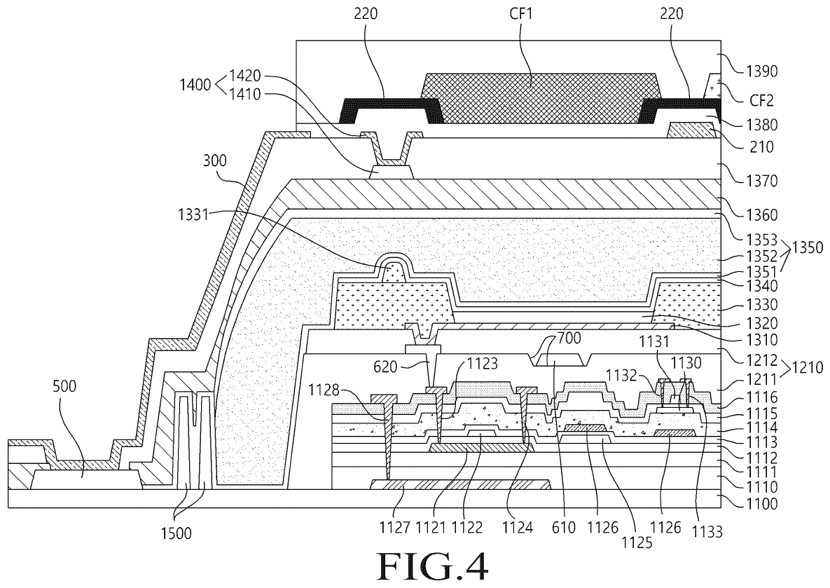

FIG. 4 is a cross-sectional view of the structure of an example portion of the active area and an example portion of the non-active area of the display device 100 according to a second example embodiment of the present disclosure.

It should be noted here that except for the recessed portion 400, the opening area OPN, and the third insulating layer 1213, the remaining elements in the stackup configuration of FIG. 3 may be substantially the same as corresponding elements in the stackup configuration of FIG. 4. Thus, for convenience of description, discussions on substantially the same elements are omitted.

Referring to FIG. 4, in the example embodiment where the display device 100 includes an insulating layer 1210 that lacks a recessed portion, a first insulating layer 1211 may be disposed on at least one of a first transistor and a second transistor and include a groove 700.

In one or more embodiments, a first metal pattern layer 610 may be disposed on the groove 700, and a first electrode layer 1310 disposed on a second insulating layer 1212 may be located on the first metal pattern layer 610, and overlap with at least a portion of the first metal pattern layer 610.

According to this example embodiment, as the depth of the groove 700 and the thickness of the metal pattern layer 610 are designed to be substantially the same, the display device 100 can provide advantages of suppressing rainbow mura caused when reflective visibility is reduced due to the step of the first electrode layer 1310, and suppressing asymmetric characteristics for each azimuth in a viewing angle color shift caused due to the step of the first electrode layer 1310.

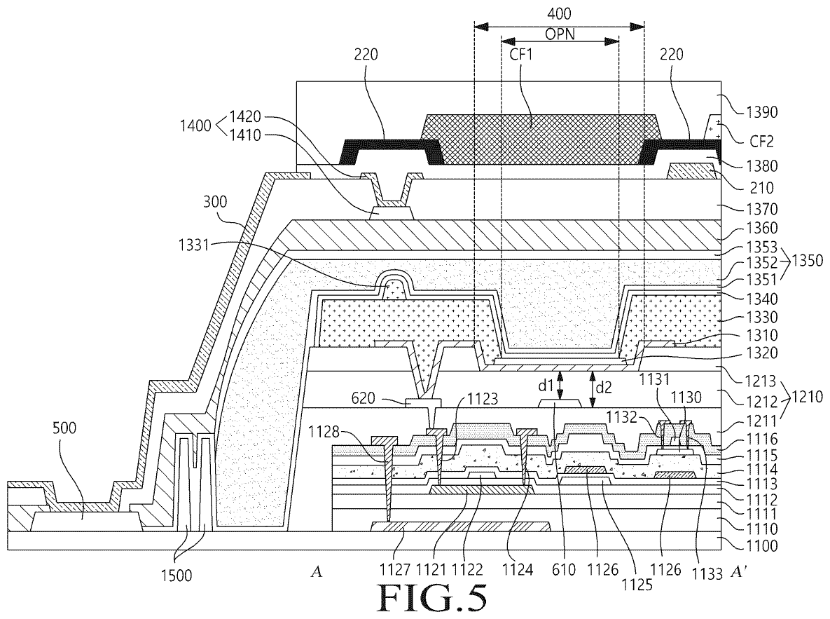

FIG. 5 is a cross-sectional view of the structure of an example portion of the active area and an example portion of the non-active area of the display device 100 according to a third example embodiment of the present disclosure.

It should be noted here that except for the third insulating layer 1213 and the groove 700, the remaining elements in the stackup configuration of FIG. 3 may be substantially the same as corresponding elements in the stackup configuration of FIG. 5. Thus, for convenience of description, discussions on substantially the same elements are omitted.

Referring to FIG. 5, a first metal pattern layer 610 may be disposed on a first insulating layer 1211, and a second insulating layer 1212 may be disposed on the first metal pattern layer 610 and the first insulating layer 1211.

In one or more embodiments, a first electrode layer 1310 may be disposed on the second insulating layer 1212, and be located on the first metal pattern layer 610 and overlap with at least a portion of the first metal pattern layer 610.

For example, in an opening area OPN of a bank layer 1330, a distance d1 between the top surface of the first metal pattern layer 610 and the bottom surface of the first electrode layer 1310 may be smaller than (e.g., less than) a distance d2 between the top surface of the first insulating layer 1211 and the bottom surface of the first electrode layer 1310.

To implement this configuration, a process, in which the second insulating layer 1212 is formed, and thereafter, the top surface of the second insulating layer 1212 is planarized, may be needed.

The top surface of the second insulating layer 1212 may be planarized through a chemical mechanical polishing (CMP) process.

Through the CMP process, pits or bumps formed in the surface of the second insulating layer 1212 caused by the first metal pattern layer 610 can be polished and flattened.

According to this example embodiment, by applying the CMP process, as the first electrode layer 1310 can be formed after the planarization without disposing an insulating layer for planarization of the second insulating layer 1212, the display device 100 can therefore provide an advantage of removing an additional process to form such an additional insulating layer.

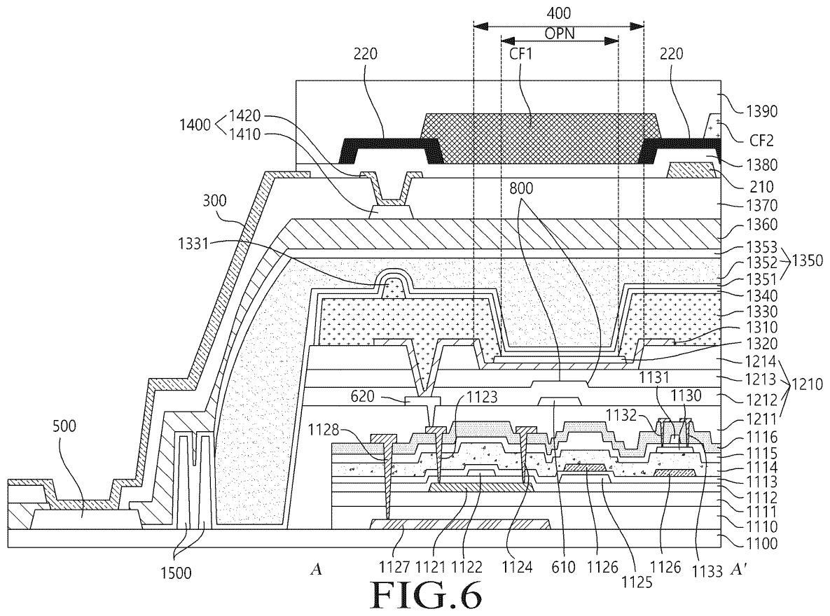

FIG. 6 is a cross-sectional view of the structure of an example portion of the active area and an example portion of the non-active area of the display device 100 according to a fourth example embodiment of the present disclosure.

It should be noted here that except for a third insulating layer 1213 and a fourth insulating layer 1214, the remaining elements in the stackup configuration of FIG. 6 may be substantially the same as corresponding elements in the stackup configuration of FIG. 5. Thus, for convenience of description, discussions on substantially the same elements are omitted.

It should be noted here that the configuration of a fourth insulating layer 1214 of FIG. 6 may be substantially the same as the configuration of a third insulating layer 1213 in FIG. 5, and the configuration of a third insulating layer 1213 of FIG. 6 may be substantially the same as the configuration of the second insulating layer 1212 in FIG. 5.

Referring to FIG. 6, a third insulating layer 1213 may be disposed between a second insulating layer 1212 and a first electrode layer 1310.

In this implementation, the second insulating layer 1212 and the third insulating layer 1213 may be referred to as a lower insulating layer and an upper insulating layer, respectively.

The top surface of the third insulating layer 1213 may contact the bottom surface of the first electrode layer 1310.

Referring to FIG. 6, a bent portion 800 disposed in a portion where the second insulating layer 1212 and the third insulating layer 1213 contact each other may be located between the top surface of a first insulating layer 1211 and the bottom surface of the first electrode layer 1310. The bent portion 800 is a protrusion in a top surface of the second insulating layer 1212 that protrudes in a direction away from the substrate 1100 due to the first metal pattern layer 610 being under the second insulating layer 1212 and the second insulating layer 1212 overlapping the metal pattern layer 610. As shown in FIG. 6, a top surface of the third insulating layer 1213 that overlaps the bent portion 800 is substantially flat.

The shape of the bent portion 800 may be substantially the same as a shape defined by the top and side surfaces of a first metal pattern layer 610 disposed on the first insulating layer 1211.

Referring to FIG. 6, as the top and side surfaces of the first metal pattern layer 610 have a sawtooth shape, the top and side surfaces of the bent portion 800 may also have a sawtooth shape.

The bent portion 800 caused by the shape of the first metal pattern layer 610 can be flattened by the third insulating layer 1213.

For example, the first electrode layer 1310 disposed on the third insulating layer 1213 can be flattened by adding a process for forming the third insulating layer 1213.

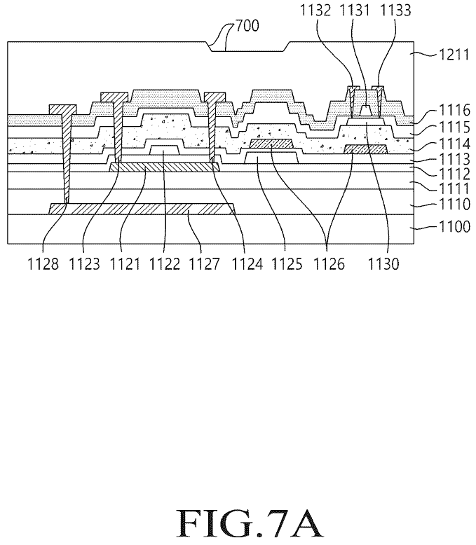

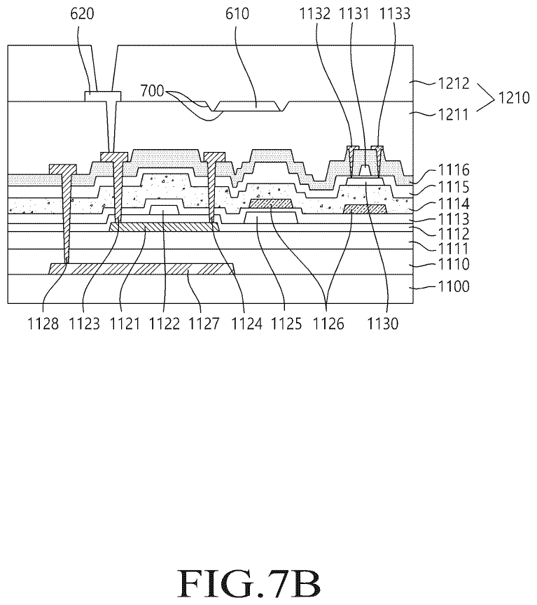

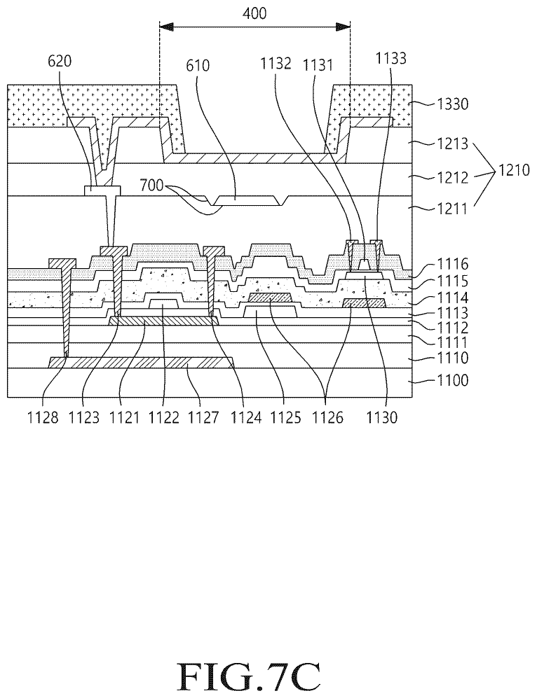

FIGS. 7A to 7C illustrate an example process of forming the structure of the active area of the display device according to the first example embodiment of the present disclosure.

Referring to FIG. 7A, the light shielding layer 1127, the first buffer layer 1110, the first transistor, and the second transistor may be sequentially disposed on the substrate 1100, and the groove 700 may be formed by applying a half tone mask (HTM).

Referring to FIG. 7B, after at least one contact hole may be formed on the first insulating layer 1211, the first metal pattern layer 610 may be formed on the groove 700, and the second metal pattern layer 620 contacting the first source electrode layer 1123 of the first transistor may be formed on the groove 700.

The first metal pattern layer 610 and the second metal pattern layer 620 may be patterned in a mesh and thereby, electrically connected with each other.

Thereafter, the second insulating layer 1212 may be formed on the first metal pattern layer 610 and the second metal pattern layer 620.

Referring to FIG. 7C, the third insulating layer 1213 may be formed on the second insulating layer 1212, and a contact hole passing through second insulating layer 1212 and the third insulating layer 1213 may be formed to allow the second metal pattern layer 620 to be contacted.

Then, the first electrode layer 1310, which contacts the second metal pattern layer 620 in a contact portion CNT where the contact hole is formed and is located on the second insulating layer 1212 and the third insulating layer 1213, may be formed, and the contact hole, which passes through the second insulating layer 1212 and the third insulating layer 1213, may be filled with the bank layer 1330.

For example, the bank layer 1330 may be located on the second insulating layer 1212 and may be configured to cover at least a portion of the first electrode layer 1310.

Referring to FIGS. 7A to 7C, as the depth of the groove 700 and the thickness of the first metal pattern layer 610 are designed to be substantially the same, pits or bumps cannot be formed in the second insulating layer 1212 in the opening area OPN, and thereby, the first electrode layer 1310 can be planarized.

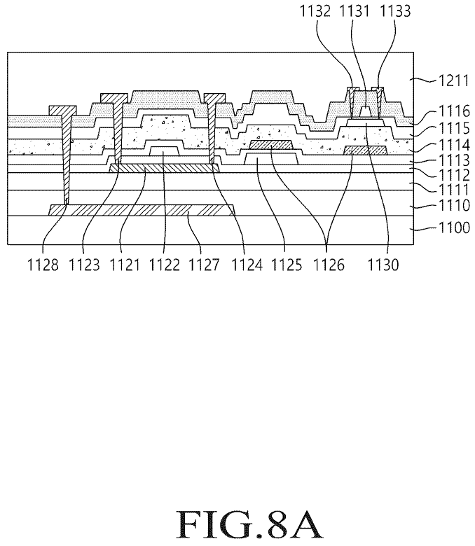

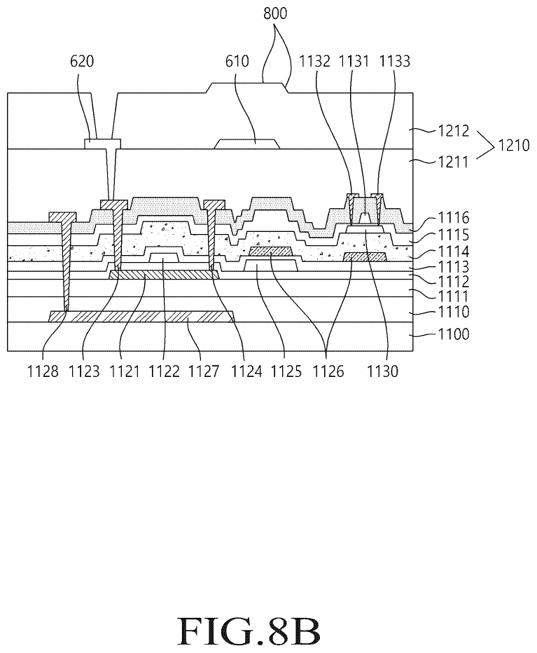

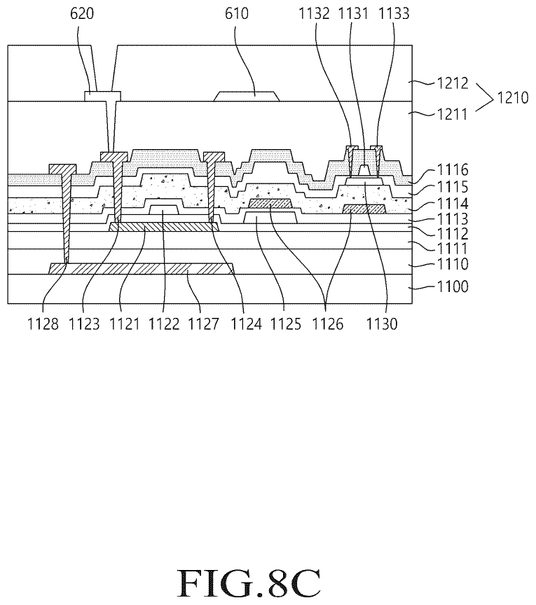

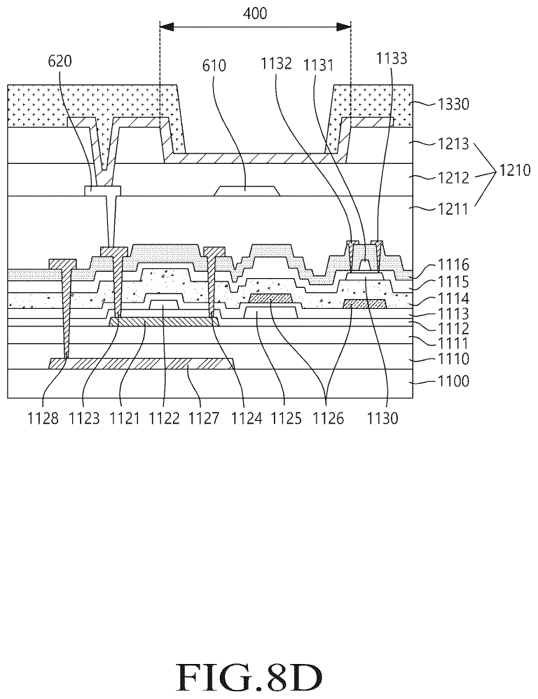

FIGS. 8A to 8D illustrate an example process of forming the structure of the active area of the display device 100 according to the third example embodiment of the present disclosure.

Referring to FIG. 8A, a light shielding layer 1127, a first buffer layer 1110, a first transistor, and a second transistor may be sequentially disposed on a substrate 1100, and the first insulating layer 1211 located on a second interlayer insulating layer 1116 and located on the first transistor and the second transistor may be formed.

Referring to FIG. 8B, a hole may be formed in the first insulating layer 1211 to allow a first source electrode layer 1123 of the first transistor to be contacted.

Then, the first metal pattern layer 610 located on the first insulating layer 1211 and a second metal pattern layer 620 contacting the first source electrode layer 1123 may be formed.

Thereafter, the second insulating layer 1212 may be formed on the first metal pattern layer 610 and the second metal pattern layer 620.

In one or more embodiments, the top surface of the second insulating layer 1212 may have a bent portion 800 with a shape defined by the top and side surfaces of the first metal pattern layer 610 due to the first metal pattern layer 610 disposed on the first insulating layer 1211.

For example, the top surface of the second insulating layer 1212 may protrude due to the first metal pattern layer 610.

A contact hole passing through the second insulating layer 1212 may be formed to allow the second metal pattern layer 620 to be contacted.

Referring to FIG. 8C, through a CMP process, pits or bumps formed in the surface of the second insulating layer 1212 caused by the first metal pattern layer 610 can be polished and flattened.

Referring to FIG. 8D, the third insulating layer 1213 may be formed on the second insulating layer 1212, and the first electrode layer 1310 contacting the second metal pattern layer 620 in a contact portion CNT where the contact hole is formed and located on the second insulating layer 1212 and the third insulating layer 1213 may be formed.

Thereafter, the contact hole in the second insulating layer 1212 and the third insulating layer 1213 may be filled with a bank layer 1330.

For example, the bank layer 1330 may be located on the second insulating layer 1212 and may be configured to cover at least a portion of the first electrode layer 1310.

Referring to FIGS. 8A to 8D, by applying the CMP process, as the first electrode layer 1310 can be formed after the planarization without disposing an insulating layer for planarization of the second insulating layer 1212, the display device 100 can therefore provide an advantage of removing an additional process to form such an additional insulating layer.

The example embodiments described above will be briefly described as follows.

According to the example embodiments described herein, a display device can be provided that includes a plurality of transistors disposed over a substrate, a first insulating layer disposed on at least one transistor among the plurality of transistors and including a groove, a metal pattern layer disposed in the groove, a second insulating layer disposed on the first insulating layer and the metal pattern layer, and an electrode layer disposed on the second insulating layer, located over the metal pattern layer, and overlapping with at least a portion of the metal pattern layer.

In one or more embodiments, a depth of the groove may be the same as a thickness of the metal pattern layer.

In one or more embodiments, the metal pattern layer may be electrically connected to the electrode layer.

In one or more embodiments, the electrode layer may include a reflective metal.

In one or more embodiments, the second insulating layer may include a recessed portion including a flat portion and an inclined portion surrounding the flat portion. The display device may further include a bank layer located on the second insulating layer, covering at least a portion of the electrode layer, and including an opening area surrounded by the inclined portion.

In one or more embodiments, a depth of the groove may be the same as a thickness of the metal pattern layer.

In one or more embodiments, the metal pattern layer may be electrically connected to the electrode layer.

In one or more embodiments, the electrode layer may include a reflective metal.

According to the example embodiments described herein, a display device can be provided that includes a plurality of transistors disposed over a substrate, a first insulating layer disposed on at least one transistor among the plurality of transistors, a metal pattern layer disposed on the first insulating layer, a second insulating layer disposed on the first insulating layer and the metal pattern layer, an electrode layer disposed on the second insulating layer, located over the metal pattern layer, and overlapping with at least a portion of the metal pattern layer, and a bank layer located on the second insulating layer, covering at least a portion of the electrode layer, and including an opening area. In one or more aspects, in the opening area, a distance between the top surface of the metal pattern layer and the bottom surface of the electrode layer may be smaller than a distance between the top surface of the first insulating layer and the bottom surface of the electrode layer.

In one or more embodiments, the second insulating layer may include a lower insulating layer disposed on the first insulating layer and the metal pattern layer, and an upper insulating layer disposed on the lower insulating layer and including a top surface contacting the bottom surface of the electrode layer. In one or more aspects, a bent portion disposed in a portion where the lower insulating layer and the upper insulating layer contact each other may be located between the top surface of the first insulating layer and the bottom surface of the electrode layer.

In one or more embodiments, the metal pattern layer may be electrically connected to the electrode layer.

In one or more embodiments, the electrode layer may include a reflective metal.

In one or more embodiments, the second insulating layer may include a recessed portion including a flat portion and an inclined portion surrounding the flat portion, and the opening area may be surrounded by the inclined portion.

In one or more embodiments, the metal pattern layer may be electrically connected to the electrode layer.

In one or more embodiments, the electrode layer may include a reflective metal.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device comprising:
a plurality of transistors over a substrate;
a first insulating layer on at least one transistor among the plurality of transistors, the first insulating layer including a groove that extends through a portion of the first insulating layer in a direction towards the substrate;
a metal pattern layer in the groove;
a second insulating layer on the first insulating layer and the metal pattern layer, the second insulating layer covering the metal pattern layer; and
an electrode layer on the second insulating layer and the metal pattern layer, the electrode layer overlapping at least a portion of the metal pattern layer.

2. The display device of claim 1, wherein a depth of the groove is a same as a thickness of the metal pattern layer.

3. The display device of claim 1, wherein the metal pattern layer is electrically connected to the electrode layer.

4. The display device of claim 1, wherein the electrode layer comprises a reflective metal.

5. The display device of claim 1, wherein the second insulating layer comprises a recessed portion in the direction towards the substrate, the recessed portion including a flat portion and an inclined portion that extends from the flat portion and surrounds the flat portion, the display device further comprising:
a bank layer on the second insulating layer and covering at least a portion of the electrode layer, the bank layer including an opening area that is surrounded by the inclined portion.

6. The display device of claim 5, further comprising:
an emission layer on the electrode layer; and
another electrode layer on the emission layer,
wherein the metal pattern layer overlaps the opening area in the bank layer, the electrode layer, the emission layer, and the other electrode layer.

7. A display device comprising:
a plurality of transistors over a substrate;
a first insulating layer on at least one transistor among the plurality of transistors;
a metal pattern layer on the first insulating layer;
a second insulating layer on the first insulating layer and the metal pattern layer;
an electrode layer on the second insulating layer and the metal pattern layer, the electrode layer overlapping with at least a portion of the metal pattern layer; and
a bank layer on the second insulating layer and covering at least a portion of the electrode layer, the bank layer including an opening area,
wherein a distance between a top surface of the metal pattern layer and a bottom surface of the electrode layer that overlaps the opening area is less than a distance between a top surface of the first insulating layer and the bottom surface of the electrode layer that overlaps the opening area.

8. The display device of claim 7, wherein the second insulating layer comprises:
a lower insulating layer on the first insulating layer and the metal pattern layer; and
an upper insulating layer on the lower insulating layer, the upper insulating layer including a top surface in contact with the bottom surface of the electrode layer,
wherein a top surface of the lower insulating layer includes a protrusion that extends in a direction away from the substrate, the protrusion overlapping the metal pattern layer.

9. The display device of claim 7, wherein the metal pattern layer is electrically connected to the electrode layer.

10. The display device of claim 7, wherein the electrode layer comprises a reflective metal.

11. The display device of claim 7, wherein the second insulating layer comprises a recessed portion that extends in a direction towards the substrate, the recessed portion including a flat portion and an inclined portion that extends from the flat portion and surrounds the flat portion, and
wherein a portion of the opening area is in the recessed portion such that the portion of the opening area is surrounded by the inclined portion.

12. A display device comprising:
a substrate;
a transistor over the substrate;
a first insulating layer over the transistor;
a first metal pattern layer on the first insulating layer;
a second insulating layer over the first metal pattern layer;
an anode electrode on the second insulating layer, the anode electrode electrically connected to the transistor;
a bank layer on the second insulating layer and a portion of the anode electrode, the bank layer having an opening;
an emission layer on the anode electrode, the emission layer overlapping the opening of the bank layer; and
a cathode electrode on the emission layer in the opening of the bank layer,
wherein a width of the first metal pattern layer is less than a width of the opening and the first metal pattern layer overlaps the opening.

13. The display device of claim 12, further comprising:
a second metal pattern layer on the first insulating layer, the second metal pattern layer connected to the transistor via a contact hole through the first insulating layer and connected to the anode electrode,
wherein the first metal pattern layer and the second metal pattern layer are electrically connected to each other.

14. The display device of claim 13, wherein the first metal pattern layer and the second metal pattern layer comprise a same material.

15. The display device of claim 12, wherein the first insulating layer includes a groove that extends through a portion of the first insulating layer in a direction towards the substrate,
wherein the first metal pattern layer is in the groove.

16. The display device of claim 15, wherein a depth of the groove is a same as a thickness of the first metal pattern layer.

17. The display device of claim 15, wherein the anode electrode comprises a reflective metal.

18. The display device of claim 15, wherein a distance between a top surface of the first metal pattern layer and a bottom surface of the anode electrode that overlap the opening is less than a distance between a top surface of the first insulating layer and the bottom surface of the anode electrode that overlaps the opening.

19. The display device of claim 15, wherein the second insulating layer comprises a recessed portion that extends in a direction towards the substrate, the recessed portion including a flat portion and an inclined portion that extends from the flat portion and surrounds the flat portion,
wherein the anode electrode contacts an inclined portion of the second insulating layer that is exposed by the inclined portion of the recessed portion and a portion of the first insulating layer that is exposed by the flat portion.

20. The display device of claim 19, wherein a portion of the opening in the bank layer is in the recessed portion and is surrounded by the inclined portion.

21. The display device of claim 15, wherein a top surface of the second insulating layer includes a protrusion that extends in a direction away from the substrate, the protrusion overlapping the first metal pattern layer.

22. The display device of claim 21, further comprising:
a third insulating layer between the second insulating layer and the anode electrode, wherein a top surface of the third insulating layer that overlaps the protrusion is substantially flat and contacts the anode electrode.
